(19) United States
(12) Patent Application Publication
(10) Pub. No.: US 2026/0122825 A1
(43) Pub. Date: Apr. 30, 2026

(54) SLIDING RAIL SECURING DEVICE

(71) Applicant: FOSITEK CORPORATION, New Taipei City (TW)

(72) Inventor: Kuan-Wei CHEN, New Taipei City (TW)

(73) Assignee: FOSITEK CORPORATION, New Taipei City (TW)

(21) Appl. No.: 19/056,115

(22) Filed: Feb. 18, 2025

(30) Foreign Application Priority Data
Oct. 30, 2024 (TW) 113141466

(51) Int. Cl. H05K 7/14

(52) U.S. Cl. CPC H05K 7/1489

(57) ABSTRACT

A sliding rail securing device includes a rear support unit, a front support unit, and a reinforcement structure. The rear support unit has at least one first through hole unit. The at least one first through hole unit each includes a plurality of first through holes that are arranged in a front-rear direction. The front support unit is adapted to be mounted to a sliding rail, is connected to the rear support unit, and is movable along an axis extending in the front-rear direction for adjusting a length of the sliding rail securing device. The reinforcement structure is mounted to the rear support unit. The reinforcement structure and the at least one first through hole unit are arranged in a top-bottom direction transverse to the front-rear direction.

### CROSS-REFERENCE TO RELATED APPLICATION

This application claims priority to Taiwanese Invention patent Application No. 113141466, filed on Oct. 30, 2024, the entire disclosure of which is incorporated by reference herein.

### FIELD

The disclosure relates to a sliding rail securing device, and more particularly to a sliding rail securing device with adjustable length.

### BACKGROUND

A conventional sliding rail securing device is adapted to mount a sliding rail to a cabinet. A server is mounted to the sliding rail, so that the server can move forwards and rearwards relative to the cabinet through the sliding rail. The conventional sliding rail securing device includes at least two components that are movable relative to each other along an axis extending in a rear-front direction. Since the at least two components are relatively movable, the length of the conventional sliding rail securing device is adjustable to fit different cabinets with different depths. When the length of the conventional sliding rail securing device is shortened, the at least two components partially overlap, and the thickness of the portion where the at least two components overlap is increased, resulting in the conventional sliding rail securing device trapping heat generated by the server, which causes bad heat dissipation. In order to solve the problem of bad heat dissipation, the conventional sliding rail securing device has a plurality of heat dissipation holes. However, the heat dissipation holes weaken the structure of the conventional sliding rail securing device, and if the server is heavy, the conventional sliding rail securing device will deform. Hence, there is room for improvement.

### SUMMARY

Therefore, an object of the disclosure is to provide a sliding rail securing device that can alleviate at least one of the drawbacks of the prior art.

According to the disclosure, the sliding rail securing device is adapted for securing a sliding rail to a cabinet. The sliding rail securing device includes a rear support unit, a front support unit, and a reinforcement structure. The rear support unit extends in a front-rear direction, is adapted to be engaged with a rear portion of the cabinet, and has at least one first through hole unit. The at least one first through hole unit each includes a plurality of first through holes that are arranged in the front-rear direction. The front support unit is elongated in the front-rear direction, is adapted to be engaged with a front portion of the cabinet, and is adapted to be mounted to the sliding rail. The front support unit is connected to the rear support unit, and is movable along an axis extending in the front-rear direction for adjusting a length of the sliding rail securing device in the front-rear direction. The reinforcement structure is elongated in the front-rear direction and is mounted to the rear support unit. The reinforcement structure and the at least one first through hole unit are arranged in a top-bottom direction transverse to the front-rear direction.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view illustrating an embodiment of a sliding rail securing device according to the disclosure and a sliding rail mounted to the sliding rail securing device.

FIG. 2 is a partially exploded perspective view of the embodiment and the sliding rail.

FIG. 3 is a fragmentary exploded perspective view of the embodiment.

FIG. 4 is another fragmentary exploded view of the embodiment similar to FIG. 3, but viewed from another angle.

FIG. 5 is a fragmentary side view illustrating a positional relationship between a rear support unit, a front support unit, and a reinforcement structure of the embodiment.

FIG. 6 is another fragmentary side view similar to FIG. 5, but a front rail is moved rearwards relative to the rear support unit.

### DETAILED DESCRIPTION

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

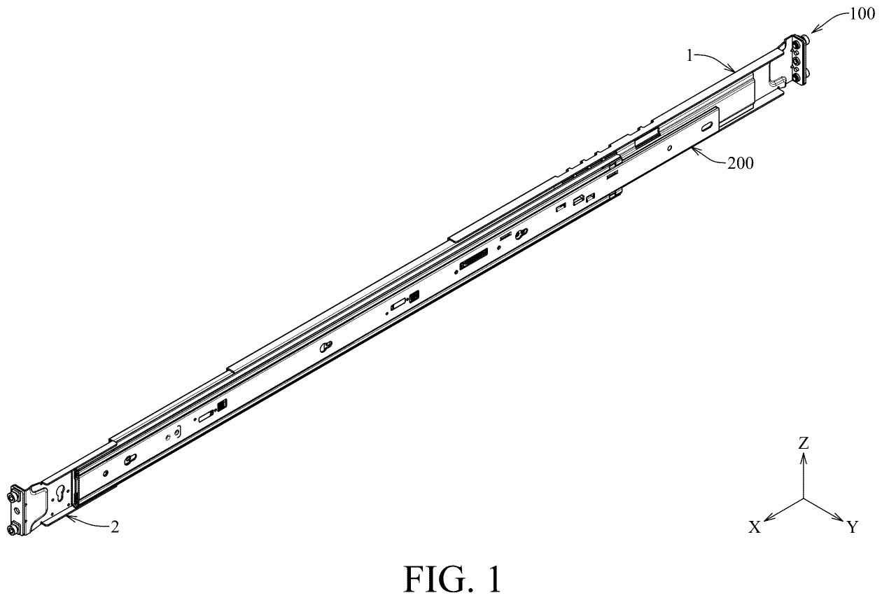

Referring to FIG. 1, it should be noted that, in the following description, a front-rear direction (X) faces forwards, a direction opposite to the front-rear direction (X) faces rearwards. A left-right direction (Y) is transverse to the front-rear direction (X), and faces leftwards. A direction opposite to the left-right direction (Y) faces rightwards. A top-bottom direction (Z) is transverse to the front-rear direction (X) and the left-right direction (Y), and faces upwards. A direction opposite to the top-bottom direction (Z) faces downwards.

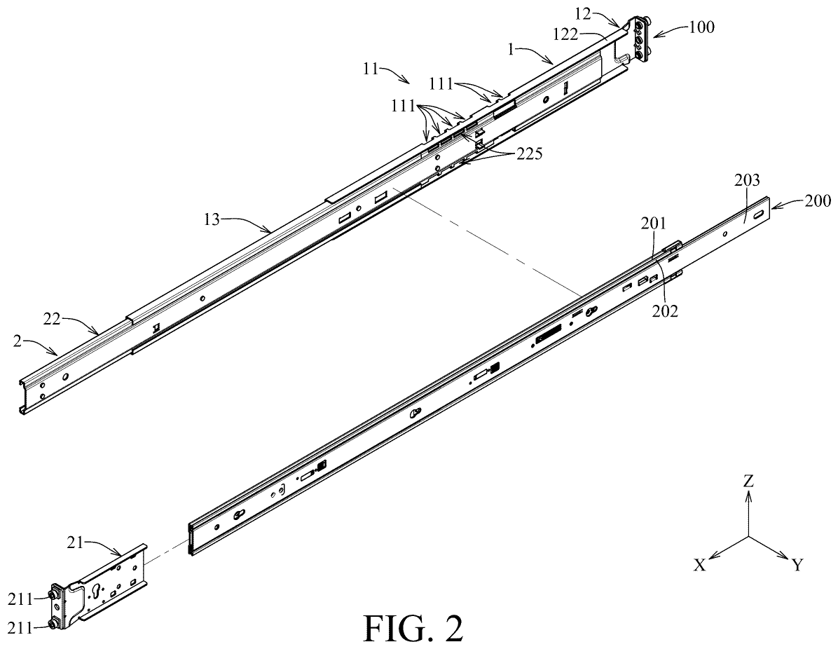

Referring further to FIG. 2, an embodiment of a sliding rail securing device 100 according to the disclosure is adapted for mounting a sliding rail 200 to one of a left part and a right part of a cabinet (not shown). The sliding rail 200 may be, for example, a three-piece sliding rail, and includes an outer rail 201 that is elongated in the front-rear direction (X), an intermediate rail 202 that is mounted to the outer rail 201, and an inner rail 203 that is mounted to the intermediate rail 202 opposite to the outer rail 201. The intermediate rail 202 and the inner rail 203 are movable along an axis extending in the front-rear direction (X). The inner rail 203 is mounted to an object such as a chassis or a drawer (not shown), so that the object can move forwards and rearwards relative to the cabinet. In this embodiment, the inner rail 203 is mounted to a chassis. In other embodiments, the sliding rail 200 may be a two-piece sliding rail where the intermediate rail 202 is omitted and the inner rail 203 is mounted to the outer rail 201. In this embodiment, the sliding rail securing device 100 is adapted to mount the sliding rail 200 to the left part of the cabinet, and the inner rail 203 is disposed on a right side of the intermediate rail 202 and is mounted to a left side of the chassis.

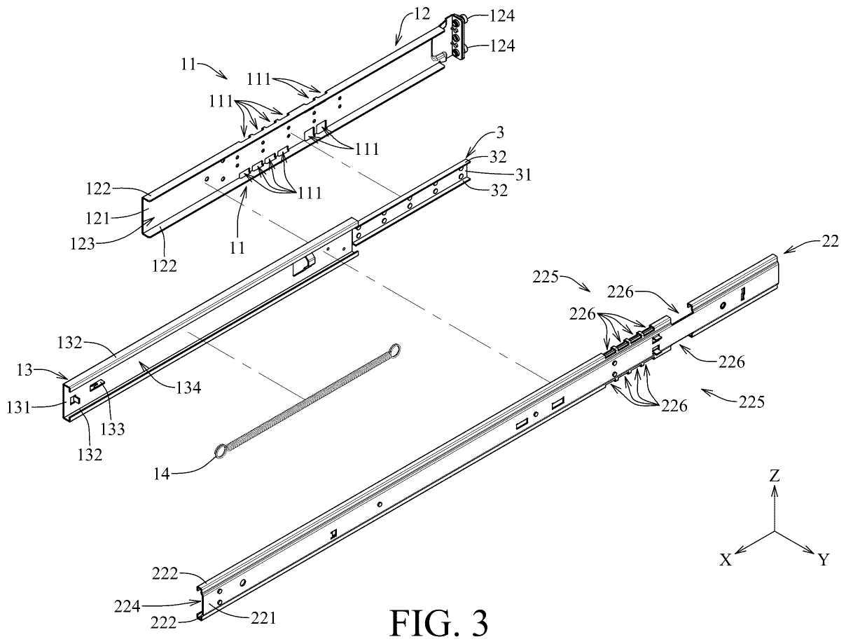

Referring to FIGS. 2 and 3, the sliding rail securing device 100 is adapted to be engaged with a front portion and a rear portion of the left part of the cabinet, and includes a rear support unit 1, a front support unit 2 that is connected to the rear support unit 1, and a reinforcement structure 3 that is mounted to the rear support unit 1. Specifically, the rear support unit 1 is adapted to be engaged with the rear portion of the left part of the cabinet, and has at least one first through hole unit 11. In this embodiment, the at least one first through hole unit 11 includes two first through hole units 11 spaced apart from each other in the top-bottom direction (Z). Each of the first through hole units 11 includes a plurality of first through holes 111 that are arranged in the front-rear direction (X). In this embodiment, there are six first through holes 111. The first through holes 111 extend through the rear support unit 1 to allow air to flow therethrough, thereby dissipating heat, and are adapted to allow wires connected to the server to extend therethrough. In other embodiments, the number of the at least one first through hole unit 11 may be one, and the first through hole unit 11 may be formed in one of a top side and a bottom side of the rear support unit 1.

Referring to FIG. 3, the rear support unit 1 includes a rear bracket 12, a rear support rail 13, and a resilient member 14. The rear bracket 12 is adapted to be engaged with the rear portion of the left part of the cabinet, and has a rear bracket base plate 121, two rear bracket side plates 122, and two rear connectors 124. The rear bracket base plate 121 is elongated in the front-rear direction (X), and has top and bottom sides that are opposite to each other in the top-bottom direction (Z). The rear bracket side plates 122 extend respectively from the top and bottom sides of the rear bracket base plate 121 in the left-right direction (Y). The rear bracket side plates 122 cooperate with the rear bracket base plate 121 to define a rear bracket slide groove 123. Each of the first through hole units 11 is formed at a junction between the rear bracket base plate 121 and a respective one of the rear bracket side plates 122. The rear connectors 124 are arranged in the top-bottom direction (Z), and extend from the rear bracket base plate 121 in a direction opposite to the front-rear direction (X). Each of the rear connectors 124 is adapted to be engaged with a corresponding one of a plurality of holes (not shown) formed in the rear portion of the left part of the cabinet, so that the rear bracket 12 is engaged with the rear portion of the left part of the cabinet. The rear support rail 13 is mounted to the rear bracket base plate 121, is proximate to the first through hole units 11, and has a rear rail base plate 131, two rear rail side plates 132, and a rear rail hook 133. The rear rail base plate 131 is elongated in the front-rear direction (X), is mounted to the rear bracket base plate 121, and has top and bottom sides opposite to each other in the top-bottom direction (Z). The rear rail side plates 132 extend respectively from the top and bottom sides of the rear rail base plate 131 in the left-right direction (Y). The rear rail hook 133 is disposed on the rear rail base plate 131 and is proximate to the front bracket 21. The rear rail side plates 132 and the rear rail base plate 131 cooperatively define a rear rail slide groove 134 that spatially communicates with the rear bracket slide groove 123.

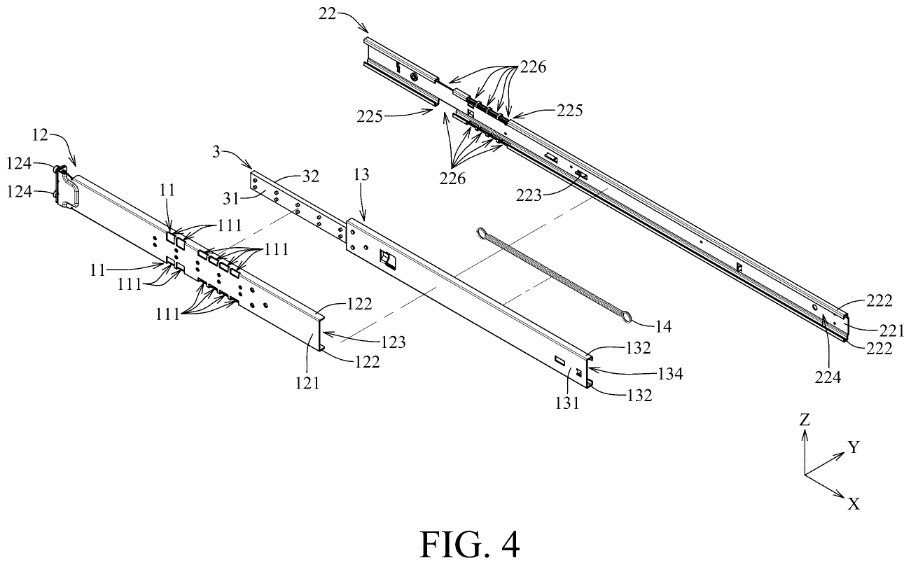

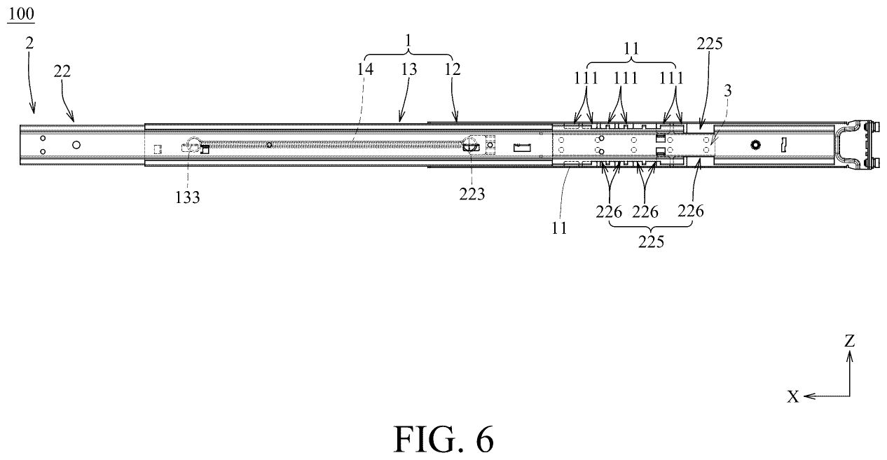

Referring to FIGS. 3 to 6, the resilient member 14 interconnects the rear support rail 13 and the front support unit 2. In this embodiment, the resilient member 14 is a tension spring, but may be a compression spring or other resilient materials in other embodiments. When the front support unit 2 is moved rearwards (see FIG. 6), the resilient member 14 is deformed and generates a resilient force to bias the front support unit 2 to move in the front-rear direction (X).

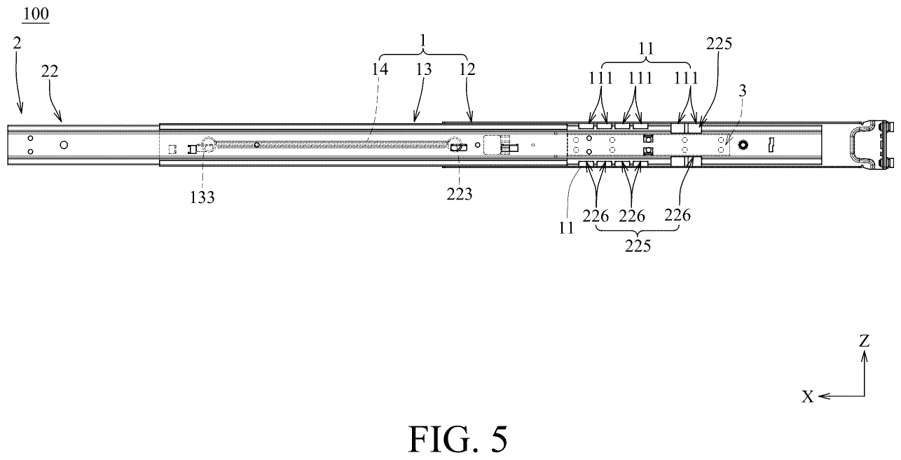

Referring to FIGS. 2 to 4, the front support unit 2 is elongated in the front-rear direction (X), is adapted to be engaged with the front portion of the cabinet, and is adapted to be mounted to the outer rail 201 opposite to the inner rail 203. The front support unit 2 is movable along an axis extending in the front-rear direction (X) for adjusting a length of the sliding rail securing device 100 in the front-rear direction (X) to fit cabinets with different lengths. Specifically, the front support unit 2 includes a front bracket 21 and a front support rail 22. The front bracket 21 extends in the front-rear direction (X), is adapted to be engaged with the front portion of the cabinet, is adapted to be mounted to the sliding rail 200, and includes two front connectors 211 extending in the front-rear direction (X). The front connectors 211 are arranged in the top-bottom direction (Z). Each of the front connecters 211 is adapted to be engaged with a corresponding one of a plurality of holes (not shown) formed in the front portion of the cabinet, so that the front bracket 21 is adapted to be mounted to the front portion of the cabinet. The front support rail 22 movably engages the rear rail slide groove 134 and the rear bracket slide groove 123, and has a front rail base plate 221, two front rail side plates 222, and a front rail hook 223. The front rail base plate 221 is elongated in the front-rear direction (X) and has top and bottom sides that are opposite to each other in the top-bottom direction. The front rail side plates 222 extend respectively from the top and bottom sides of the front rail base plate 221 in a direction opposite to the left-right direction (Y). The front rail hook 223 is disposed on the front rail base plate 221 and is proximate to the rear support unit 1. The front rail base plate 221 further has a contact surface that is disposed between the top and bottom sides, that is opposite to the front rail side plates 222, and that is adapted to be mounted to the sliding rail 200. The front rail base plate 221 and the front rail side plates 222 cooperatively define an accommodation space 224 for accommodating the reinforcement structure 3. Each of the rear rail side plates 132 is disposed between a respective one of the front rail side plates 222 and a respective one of the rear bracket side plates 122. In this embodiment, the front rail hook 223 is connected to a rear portion of the resilient member 14, and the rear rail hook 133 is connected to a front portion of the resilient member 14. When the sliding rail securing device 100 is disengaged from the cabinet, the resilient member 14 biases the front support rail 22 to move forwardly to reset a position of the front support unit 2 (see FIG. 5).

Referring to FIG. 3, the front support rail 22 further has two second through hole units 225. Each of the second through hole units 225 is formed at a junction between the front rail base plate 221 and a respective one of the front rail side plates 222. Each of the second through hole units 225 includes a plurality of second through holes 226 that are arranged in the front-rear direction (X). In this embodiment, for each of the second through hole units 225, a number of the second through holes 226 is five. The second through holes 226 extend through the front support rail 22 and spatially communicate with the first through holes 111 to allow air to flow therethrough, thus dissipating heat, and are adapted to allow the wires connected to the server to pass therethrough. Referring to FIG. 5, when the front support rail 22 is at a normal position, a portion of the front support rail 22 protrudes from the rear support rail 13. At this time, the resilient member 14 is not stretched (i.e., a length of the resilient member 14 is not changed), and each of the second through hole units 225 substantially overlaps a respective one of the first through hole units 11. Referring to FIG. 6, when the rear connectors 124 are engaged with the holes of the rear portion of the left part of the cabinet, the front support rail 22 is rearwards movable relative to the rear support rail 13, which causes the resilient member 14 to resiliently deform and generate a resilient force for biasing the front support unit 2 in the front-rear direction (X). At this time, a length of the portion of the front support rail 22 protruding from the rear support rail 13 is shorter than the length of the portion of the front support rail 22 protruding from the rear support rail 13 when the front support rail 22 is at the normal position (i.e., the overall length of the sliding rail securing device 100 is shortened), the second through hole units 225 are displaced from the first through hole units 11, so that a larger portion of the second through holes 226 are blocked by the rear bracket 12 and a smaller portion of the second through holes 226 remains to spatially communicate with the first through holes 111, thereby allowing the front bracket 21 to move to be aligned with the holes of the front portion of the cabinet. When the front connectors 211 are moved to be precisely aligned with the holes of the front portion of the cabinet, the front support rail 22 and the sliding rail 200 are forwardly moved relative to the rear support rail 13 by the resilient force of the resilient member 14, until the front connectors 211 engage the holes of the front portion of the cabinet. It should be noted that, a length of the sliding rail securing device 100 is, when the front support rail 22 is at the normal position, longer than a length of the sliding rail securing device 100 when the front support rail 22 is moved rearwards.

The reinforcement structure 3 is elongated in the front-rear direction (X), is mounted to the rear support unit 1, and is proximate to front support unit 2. Specifically, the reinforcement structure 3 is disposed between the rear bracket base plate 121 and the front support unit 2 in the left-right direction (Y). The reinforcement structure 3 and the first through hole units 11 are arranged in the top-bottom direction (Z), and the reinforcement structure 3 is disposed between the first through hole units 11. The reinforcement structure 3 has a reinforcement base plate 31 elongated in the front-rear direction (X) and having top and bottom sides that are opposite to each other in the top-bottom direction (Z), and two reinforcement side plates 32 extending respectively from the top and bottom sides of the reinforcement base plate 31 in the left-right direction (Y). The reinforcement side plates 32 abut against the front support rail 22 to prevent deformation. The reinforcement structure 3 reinforces a structure of the rear support unit 1 by providing support forces in the top-bottom direction (Z) and in the left-right direction (Y). By virtue of the configurations of the reinforcement structure 3 and the first through hole units 11, the first through hole units 11 are unobstructed by the reinforcement structure 3, and the structure of the rear support unit 1 is reinforced by the reinforcement structure 3, which prevents the rear support unit 1 from being twisted and deforming, thereby increasing durability of the rear support unit 1. In this embodiment, the reinforcement structure 3 is riveted to the rear bracket base plate 121, which prevents the reinforcement structure 3 from easily disengaging from the rear bracket base plate 121. In this embodiment, the reinforcement structure 3 is made by stamping and bending a metal sheet.

Specifically, the reinforcement structure 3 is disposed in the accommodating space 224 and the rear bracket slide groove 123, which decreases a thickness of the sliding rail securing device 100 in the left-right direction (Y). Moreover, in other embodiments, the reinforcement structure 3 and the rear support rail 13 may be integrally formed for steadier support from the reinforcement structure 3.

In conclusion, by virtue of the configurations of the rear support unit 1 and the reinforcement structure 3, the first through hole units 11 are not obstructed by the reinforcement structure 3, and the structure of the rear support unit 1 is strengthened and prevented from deformation, which increases durability of the sliding rail securing device 100. Hence, the objective of the disclosure is achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A sliding rail securing device adapted for securing a sliding rail to a cabinet, said sliding rail securing device comprising:
a rear support unit that extends in a front-rear direction, that is adapted to be engaged with a rear portion of the cabinet, and that has at least one first through hole unit, said at least one first through hole unit each including a plurality of first through holes that are arranged in the front-rear direction;
a front support unit that is elongated in the front-rear direction, that is adapted to be engaged with a front portion of the cabinet, that is adapted to be mounted to the sliding rail, that is connected to said rear support unit, and that is movable along an axis extending in the front-rear direction for adjusting a length of said sliding rail securing device in the front-rear direction; and
a reinforcement structure that is elongated in the front-rear direction and that is mounted to said rear support unit, said reinforcement structure and said at least one first through hole unit being arranged in a top-bottom direction transverse to the front-rear direction.

2. The sliding rail securing device as claimed in claim 1, wherein said at least one first through hole unit includes two first through hole units spaced apart from each other in the top-bottom direction, said reinforcement structure being disposed between said first through hole units.

3. The sliding rail securing device as claimed in claim 2, wherein:
said rear support unit includes a rear bracket that is adapted to be engaged with the rear portion of the cabinet, and that has
a rear bracket base plate elongated in the front-rear direction, and having a top side and a bottom side that are opposite to each other in the top-bottom direction, and
two rear bracket side plates extending respectively from said top side and said bottom side of said rear bracket base plate in a left-right direction transverse to the front-rear direction and the top-bottom direction, said rear bracket side plates cooperating with said rear bracket base plate to define a rear bracket slide groove, said front support unit movably engaging said rear bracket slide groove;
each of said first through hole units is formed at a junction between said rear bracket base plate and a respective one of said rear bracket side plates; and
said reinforcement structure is disposed between said rear bracket base plate and said front support unit.

4. The sliding rail securing device as claimed in claim 3, wherein said rear support unit further includes a rear support rail mounted to said rear bracket and proximate to said first through hole units, and a resilient member interconnecting said rear support rail and said front support unit.

5. The sliding rail securing device as claimed in claim 4, wherein:
said rear support rail has
a rear rail base plate that is elongated in the front-rear direction, that is mounted to said rear bracket base plate, and that has a top side and a bottom side opposite to each other in the top-bottom direction, and
two rear rail side plates that extend respectively from said top side and said bottom side of said rear rail base plate in the left-right direction;
said rear rail side plates and said rear rail base plate cooperatively define a rear rail slide groove; and
said rear bracket slide groove spatially communicates with said rear rail slide groove, said front support unit movably engaging said rear rail slide groove.

6. The sliding rail securing device as claimed in claim 5, wherein said front support unit includes:
a front bracket that is adapted to be engaged with the front portion of the cabinet and that is adapted to be mounted to the sliding rail; and
a front support rail that movably engages said rear rail slide groove and said rear bracket slide groove, and that has
a front rail base plate elongated in the front-rear direction and having a top side and a bottom side that are opposite to each other in the top-bottom direction, and
two front rail side plates extending respectively from said top side and said bottom side of said front rail base plate in a direction opposite to the left-right direction, said front rail base plate and said front rail side plates cooperatively defining an accommodation space for accommodating said reinforcement structure, said front rail base plate further having a contact surface that is disposed between said top side and said bottom side, that is opposite to said front rail side plates, and that is adapted to be mounted to the sliding rail device.

7. The sliding rail securing device as claimed in claim 6, wherein said reinforcement structure has a reinforcement base plate elongated in the front-rear direction and having a top side and a bottom side that are opposite to each other in the top-bottom direction, and two reinforcement side plates extending respectively from said top side and said bottom side of said reinforcement base plate in the left-right direction.

8. The sliding rail securing device as claimed in claim 7, wherein said reinforcement structure is riveted to said rear bracket base plate.

9. The sliding rail securing device as claimed in claim 6, wherein said front support rail further has two second through hole units, each of said second through hole units being formed at a junction between said front rail base plate and a respective one of said front rail side plates, each of said second through hole units including a plurality of second through holes that are arranged in the front-rear direction.

10. The sliding rail securing device as claimed in claim 4, wherein said reinforcement structure and said rear support rail are integrally formed.
